(19) United States
(12) Patent Application Publication
(10) Pub. No.: US 2020/0357939 A1
(43) Pub. Date: Nov. 12, 2020

(54) ULTRASENSITIVE PHOTODETECTORS

(71) Applicant: THE REGENTS OF THE UNIVERSITY OF CALIFORNIA, Oakland, CA (US)

(72) Inventors: Matthew D. Law, Irvine, CA (US); Chao Yi, Irvine, CA (US)

(21) Appl. No.: 16/796,583

(22) Filed: Feb. 20, 2020

Related U.S. Application Data
(60) Provisional application No. 62/809,917, filed on Feb. 25, 2019.

(51) Int. Cl. H01L 31/0336; H01L 31/0352; H01L 31/18; H01L 31/0216

(52) U.S. Cl. CPC H01L 31/0336; H01L 31/02161; H01L 31/18; H01L 31/035218

(57) ABSTRACT

The present invention pertains to photodetectors based on colloidal quantum dot films. An ultrathin layer of metal oxide deposited at the heterojunction interface by atomic layer deposition (ALD) results in quantum dot infrared photodetectors with increased photocurrent, decreased dark current, and world-record specific detectivity of >2×10¹² Jones for 2000-2550 nm at room temperature and zero applied bias. This detectivity is an order of magnitude higher than the detectivity of commercial detectors and better than any previously-published nanomaterial. In addition to record sensitivity, the devices of the present invention have large linear dynamic range (>120 dB) and good speed (39 kHz). The device fabrication is amenable to making detector arrays at the wafer scale. It has been shown that the thin metal oxide interlayer passivates interfacial defect states, which results in the lower dark current and improved photocurrent at zero bias.

### CROSS-REFERENCES TO RELATED APPLICATIONS

This application is a non-provisional and claims benefit of U.S. Provisional Application No. 62/809,917 filed Feb. 25, 2019, the specification(s) of which is incorporated herein in their entirety by reference.

### STATEMENT REGARDING FEDERALLY SPONSORED RESEARCH OR DEVELOPMENT

This invention was made with government support under Contract No. FA8650-16-C-7638 awarded by the Air Force Research Laboratory (AFRL) and the Defense Advanced Research Projects Agency (DARPA). The government has certain rights in the invention.

### FIELD OF THE INVENTION

The present invention relates to photodetectors. More specifically, the present invention relates to ultrasensitive quantum dot-based photodetectors.

### BACKGROUND OF THE INVENTION

Photodetectors for visible light have high performance and relatively low cost, but photodetectors for infrared light suffer from low performance and high cost, which prevents most non-military, mass market applications. Commercial infrared photodetectors are mostly based on very expensive epitaxial thin-films like InGaAs and HgCdTe that must be cooled to achieve good performance. Less expensive commercial devices based on PbS thin-films are also available, but their performance is worse. Critical to increasing performance is to decrease dark current, increase photocurrent, and improve speed. Critical to decreasing cost is to adopt low-cost fabrication at the wafer scale and operate the devices at room temperature, thereby avoiding the need for expensive and heavy/bulky cryogenic cooling of the detectors. Many new photodetector materials are under development, including 2D materials (e.g., graphene), nanowires, organics, and quantum dots, but the performance of these materials outside of the visible part of the spectrum is not sufficient for commercial applications. Of these alternative materials, quantum dots have shown the best results and the most promise, but researchers have so far failed to make high-performance devices in several important spectral regions, including the short-wave infrared (1-1.7 microns) and extended short-wave infrared (1.7-3.0 microns), mostly because of poorly-performing interfaces and bad current collection (charge transport). Breakthroughs in materials quality and device design are needed to achieve high-performance, low-cost infrared photodetectors that operate at room temperature.

Unlike mid-wave infrared (MWIR) and long-wave infrared (LWIR) cameras, SWIR cameras typically detect photons reflected from a subject that is passively illuminated by sunlight or nighttime airglow, thereby providing the sharp contrast between reflected and absorbed light needed for high-resolution day-and-night imaging. Due to reduced scattering at longer wavelengths, SWIR imagers can see through rain, fog, haze, smoke, and dust, which is useful for remote sensing, surveillance, maritime navigation, firefighting, and autonomous vehicles. The strong reflectivity contrast of materials in the SWIR band can be leveraged for mineral mapping, environmental monitoring, materials identification, forensics, and industrial quality control. In addition, hot objects (>150° C.) show appreciable SWIR emission, enabling SWIR thermal imaging for manufacturing and disaster response (e.g., monitoring fires and lava flows). eSWIR detectors are particularly underdeveloped despite the utility of this part of the electromagnetic spectrum for navigation in adverse weather conditions, environmental monitoring, disaster response, and night vision.

### BRIEF SUMMARY OF THE INVENTION

It is an objective of the present invention to provide systems, devices, and method that allow for high-performance photodetectors, as specified in the independent claims. Embodiments of the invention are given in the dependent claims. Embodiments of the present invention can be freely combined with each other if they are not mutually exclusive.

The present invention pertains to photodetectors based on colloidal quantum dot films. An ultrathin layer of metal oxide deposited at the heterojunction interface (i.e., the interface between the quantum dots and the other semiconductor layer) by atomic layer deposition (ALD) results in quantum dot (QD) infrared photodetectors with increased photocurrent, decreased dark current, and world-record specific detectivity (the standard measure of the sensitivity of a photodetector) of >2×10¹² Jones for 2000-2550 nm at room temperature and zero applied bias. This detectivity is an order of magnitude higher than the detectivity of commercial detectors and better than any previously-published nanomaterial. In addition to record sensitivity, the devices have large linear dynamic range (>120 dB) and good speed (39 kHz). The device fabrication is amenable to making detector arrays (cameras) at the wafer scale. It has been shown that the thin metal oxide interlayer passivates interfacial defect states, which results in the lower dark current and improved photocurrent at zero bias (zero bias operation is called “photovoltaic mode”). Although quantum dot eSWIR photodetectors and a titanium oxychloride interlayer are used to demonstrate the effectiveness of the invention, this ALD “interface modification” or “interface engineering” method is believed to be of general use for improving the performance of photodetectors and other optoelectronic devices based on nanomaterials or thin-films. ALD interface engineering is the key for enabling high quantum dot device performance in the eSWIR band. In fact, it is believed that this method/strategy will result in record-performance quantum dot detectors throughout the infrared spectrum.

One of the unique and inventive technical features of the present invention is the interface modification between two semiconductive materials using an ultrathin interfacial layer deposited using ALD. Without wishing to limit the invention to any theory or mechanism, it is believed that the technical feature of the present invention advantageously provides for the passivation of defect states in one of the semiconductive materials and also modifies the interfacial barrier height. None of the presently known prior references or work has the unique inventive technical feature of the present invention. Furthermore, the prior references teach away from the present invention. For example, the prior art focuses on modifying the quantum dot film itself rather than the surface which interfaces with the QD film because it is commonly believed that poor charge transport in the QD film is the main limitation on photodetector performance. It is surprising that modification of the interface with an ultrathin interfacial layer provides for ultrasensitive QD photodetector devices.

Furthermore, the inventive technical features of the present invention contributed to a surprising result. For example, the performance of the devices of the present invention is the best ever reported. Their detectivity of 2×10¹² Jones for 2000-2550 nm light at room temperature is one order of magnitude better than commercial detectors. This detectivity is also higher than for any previously reported nanomaterial. Linear dynamic range of >120 dB rivals the best commercial detectors and is superior to most previous nanomaterials. Although not as fast as commercial IR photodiodes, the device speed of 39 kHz is sufficient for many applications. These devices are made by low-cost solution processing and a very short ALD step. They can be made at the wafer scale, which is critical for lowering the cost of IR cameras. In summary, the methods and devices of the present invention combine record detectivity and high dynamic range and speed with much lower cost fabrication. While the included example embodiments demonstrate the advantages for one part of the spectrum (the eSWIR band), it is believed that both the method and device design are general to other wavelengths.

Any feature or combination of features described herein are included within the scope of the present invention provided that the features included in any such combination are not mutually inconsistent as will be apparent from the context, this specification, and the knowledge of one of ordinary skill in the art. Additional advantages and aspects of the present invention are apparent in the following detailed description and claims.

### BRIEF DESCRIPTION OF THE SEVERAL VIEWS OF THE DRAWINGS

The patent application contains at least one drawing executed in color. Copies of this patent or patent application publication with color drawing(s) will be provided by the office upon request and payment of the necessary fee.

The features and advantages of the present invention will become apparent from a consideration of the following detailed description presented in connection with the accompanying drawings in which:

FIGS. 1A-1D show PbSe quantum dot eSWIR photodiodes. FIG. 1A shows an illustration of the device layout. FIG. 1B shows a typical extinction spectrum of the cubic PbSe QDs in tetrachloroethylene solution. The shading denotes the eSWIR band. The inset shows a TEM image of a typical QD, with a 5 nm scale bar. FIG. 1C shows a top-down SEM image of an EDT-treated QD film (200±5 nm thick). The scale bar is 100 nm. FIG. 1D shows a cross-sectional SEM image of a device with ITO (135 nm)/ZnO (65 nm)/QDs (175 nm)/Au (25 nm). The scale bar is 100 nm.

FIGS. 2A-2C shows the impact of ALD interface engineering on photodetector performance. FIG. 2A shows typical dark (dashed lines) and illuminated (solid lines) J-V curves for devices with and without 5 cycles of ALD TiOx grown on the nanocrystalline ZnO layer at 200° C. prior to QD film deposition. The QD film thickness of 200±5 nm was chosen because it gave maximum eSWIR photoresponse. FIG. 2B shows detector responsivity as a function of the number of ALD cycles at three ALD growth temperatures. Responsivity is reported for zero applied bias (photovoltaic mode). Error bars denote the standard deviation for four devices. Responsivity also showed a dependence on the N2 flow rate used during the ALD process. FIG. 2C shows measured specific detectivity (D*) of devices without a TiOₓ interlayer versus devices with 5 cycles of ALD TiOx deposited at the three temperatures. D* is also reported for zero bias. Error bars are smaller than the data points. All measurements were performed at room temperature using light from a filtered tungsten lamp (λ=2.0-2.55 μm, 5.3 mW cm⁻²).

FIGS. 3A-3C shows the detector dynamic range and speed. FIG. 3A shows a graph of photocurrent and responsivity versus light intensity (A=2.0-2.55 μm, 19 nW cm⁻²-21 mW cm⁻²). R is nearly constant and the linear dynamic range is >120 dB. FIG. 3B shows a graph of transient photoresponse under pulsed illumination with an infrared LED (A=2350 nm, 0.77 mW cm⁻²) using square-wave light pulses of 5-200 μs pulse width. The time traces have been overlaid near the origin for clarity. FIG. 3C shows a magnified time trace for a 100 μs light pulse. The 10-90% rise and fall times are 9 μs, which correspond to a −3 dB bandwidth of 38.9 kHz. The TiOₓ interlayer deposition conditions were 5 cycles at 200° C.

FIGS. 4A-4C show photoluminescence and photoelectron spectroscopy results. FIG. 4A shows PL spectra of bare and TiOx-coated ZnO films made using different ALD temperatures (5 ALD cycles). The TiOx coating suppresses the ZnO defect emission at 2.18 eV. Annealing alone (without TiOx deposition) has no effect on the defect emission. The spectrum of a bare quartz substrate is also shown. FIG. 4B shows energy levels of bare ZnO, TiOx-coated ZnO (5 cycles at 200° C.), and QD films as determined from XPS/UPS data. The uncertainty in the position of the Fermi level (EF), valence band maximum (EVBM), and conduction band minimum is ±0.15, ±0.25 eV and ±0.25 eV, respectively. Band gaps are taken from optical absorption spectra. All three films seem n-type and the TiOx coating does not change the ZnO energy levels. VB=valence band. CB=conduction band. FIG. 4C shows equilibrium band diagrams of the devices calculated with the 1D Poisson software package. Plotted in red is the diagram for devices with or without a TiOx interlayer according to the XPS/UPS data in FIG. 4B. Plotted in blue is a proposed band diagram that assumes the TiOx interlayer produces an interface dipole that shifts the bands of the ZnO/TiOx layer down in energy by 0.2 eV (half of the measured band offset between the individual ZnO/TiOx and QD films). In both calculations, EF of the ZnO, ZnO/TiOx, and QD films is ˜0.1 eV below the conduction band, rather than within it as shown in FIG. 4B, and the work functions of ITO and gold are 4.7 eV and 5.1 eV, respectively.

FIGS. 5A-5B show QD shape and size distribution data. FIG. 5A shows a representative TEM image of the truncated cubic QDs. The scale bar is 20 nm. FIG. 5B shows a histogram of the cubic edge length of 220 QDs. The edge length is 7.3±0.3 nm.

FIGS. 6A-6B show optical extinction spectra of QD solutions and films. FIG. 6A shows, the extinction spectra of eight different batches of PbSe QDs with first exciton absorption peaks at 2.3-2.5 μm (corresponding to absorption onsets of 2.7-2.9 μm). The five batches with absorption peaks at ˜2.3 μm were used in this example. FIG. 6B shows extinction spectra for a typical batch of QDs in solution (red), after spin coating to form a film of oleate-capped QDs (blue), and after ligand exchange of the film with EDT (green). Ligand exchange redshifts the exciton peak from 2346 nm to 2398 nm.

FIGS. 7A-7C show FTIR transmission spectra of the QD films. FIG. 7A shows typical FTIR spectra of oleate-capped and EDT-treated films showing both the ligand vibrations and the first exciton absorption peak (the 1Sₕ-1Sₑ transition) of the QDs. The film thickness is 110±5 nm. FIG. 7B shows a magnified view of the C—H stretching region. The EDT-treated film data have been multiplied by a factor of twelve to facilitate comparison with the spectrum of the oleate-capped film. Peak energies are labeled. FIG. 7C shows a magnified view of the —COO stretching region. Peak energies are labeled. It was concluded that oleate is completely removed during ligand exchange and the residual C—H stretching signal is due to EDT, perhaps with some contribution from unknown hydrocarbon contaminants.

FIGS. 8A-8I show X-ray photoelectron spectra of a representative EDT-treated QD film on a silicon substrate. FIG. 8A shows an indexed survey scan. FIG. 8B shows the O 1s spectrum. FIG. 8C shows the Pb 4f spectrum. FIG. 8D shows the Se 3d spectrum. FIG. 8E shows the secondary electron cutoff. FIG. 8F shows the Se 3s and S 2s spectrum. FIG. 8G shows the C 1s spectrum. FIG. 8H shows the x-ray valence band. Only Pb, Se, S, and C were detected. The lack of oxygen is consistent with complete removal of oleate during exchange with EDT. From the secondary electron cutoff energy, the work function (Fermi level) is estimated to be ϕₛ=E_{F}=4.55±0.15 eV. The valence band spectrum shows that the energy difference between E_{F} and the valence band maximum (E_{F}−E_{VBM}) is 0.52±0.2 eV, which is similar to the optical band gap (0.517 eV) and indicates moderate-to-strong n-type doping of these QD films. The data place E_{VBM} at 5.07±0.25 eV below the vacuum level. See FIG. 4B for the corresponding energy level diagram. FIG. 8I shows a table which summarizes the film elemental composition, E_{F}, and E_{VBM} as determined from the XPS data.

FIGS. 9A-9B show Spectral irradiance of the infrared light source. FIG. 9A shows the spectral irradiance of the Thorlabs SLS202L stabilized tungsten IR light source (left axis) and the transmission spectrum of the IR bandpass filter (right axis). FIG. 9B shows the spectral irradiance of the filtered source passing (left axis) and the integrated power density (right axis). The total power density is 5.3 mW cm⁻², which is consistent with the power measured by a pyroelectric radiometer.

FIGS. 10A-10D show the characterization of light absorption by the detectors. FIG. 10A shows transmittance (T), reflectance (R), and absorptance (A) of a complete detector [ITO (135 nm)/ZnO (65 nm)/QDs (200 nm)/Au (35 nm)] measured using an integrating sphere. FIG. 10B shows the photon flux of the incident light and absorbed light. The device absorbs 68% of the incident photons. FIG. 10C shows the current density integrated across the incident photon flux assuming 100% external quantum efficiency (J_{incident}) versus only 100% internal quantum efficiency (J_{absorbed}). The measured current density of 2.8 mA cm⁻² (Jₘₑₐₛ) represents an EQE of 29% and an IQE of 43%. FIG. 10D shows transmittance (T), reflectance (R), and absorptance (A) of the ITO-coated glass substrate.

FIG. 11 shows QD film thickness optimization. Detector responsivity versus QD film thickness for devices with TiOₓ interlayers made at 150° C. (5 cycles of ALD). The sharp peak in responsivity is driven primarily by optical interference within the device stack that maximizes light absorption in the QD layer for certain film thicknesses. Responsivity error bars show the standard deviation for 6-8 devices. Thickness error bars were determined from cross-sectional SEM images of single devices.

FIG. 12 shows a graph of the effect of ALD inert gas flow rate on detector responsivity. Responsivity versus the N₂ flow rate used to deposit the ALD TiOₓ interlayer (5 cycles @ 200° C.). The QD film thickness is 200 nm. Error bars show the range of values for two devices.

FIGS. 13A-13B show Current noise characteristics of the detectors. FIG. 13A shows the typical current noise spectral density (1-100 Hz) for devices as a function of TiOₓ deposition temperature (no TiOₓ vs. 5 cycles of TiOₓ at 75° C., 150° C., or 200° C.). The increased noise at low frequencies originates from the spectrum analyzer and measurement circuit rather than the devices under test. FIG. 13B shows a magnified plot of the current noise spectral density at the higher frequencies (10-100 Hz) for devices without a TiOₓ interlayer and with an interlayer grown at 200° C. (5 cycles). The calculated shot noise spectral density Iₛ(f) (Iₛ=\sqrt{2qI_{d}}, where I_{d} is the dark current and q the electron charge) is indicated by the hashed horizontal lines.

FIG. 14 shows a table of the most sensitive commercially-available eSWIR detectors at room temperature are PbS thin-film photoconductors (D*˜1×10¹¹ Jones at 2200 nm) and reverse-biased InGaAs photodiodes (D*˜1×10¹¹ Jones at 2300 nm). D* of these commercial detectors is a factor of ˜100 lower than BLIP for detectors that see the thermal background.

FIG. 15 shows the photoluminescence spectra of the ZnO films on ITO-coated glass substrates. PL spectra as a function of ALD conditions (no TiOₓ versus 5 cycles of TiOₓ deposited at 75° C., 150° C., and 200° C.). Also shown are control spectra of a sample annealed in the ALD chamber at 200° C. for 30 minutes (but without TiOₓ deposition) and a bare ITO substrate. All of the spectra except that of the bare substrate are normalized at the ZnO band edge emission peak at 3.31 eV. The excitation wavelength was 330 nm (3.76 eV).

FIG. 16 shows the data of a control experiment showing the negligible effect of ZnO annealing on detector responsivity. Responsivity versus annealing temperature for devices (200 nm QD films) made by annealing ZnO-coated ITO/glass substrates in the ALD chamber without TiOₓ deposition (no TiOₓ interlayer). The annealing time (30 minutes) was identical to the time devices spend at elevated temperature for ALD TiOₓ growth. Annealing alone without TiOₓ deposition has a minimal effect on detector responsivity. The error bars show the spread in values for 2-3 devices.

FIGS. 17A-17F show x-ray photoelectron spectra of bare and TiOₓ-coated nanocrystalline ZnO films. Compiled here is an indexed survey scan and high-resolution spectra of the Zn 2p, Ti 2p, O 1s, C 1s, and CI 2p regions for bare and TiOₓ-coated (5 cycles at 75° C., 150° C., and 200° C.) ZnO films on ITO-coated glass substrates. FIG. 17A shows the indexed survey scan. FIG. 17B shows the Zn 2p spectrum. FIG. 17C shows the Ti 2p spectrum. FIG. 17D shows the O 1s spectrum. FIG. 17E shows the C 1s spectrum. FIG. 17F shows the Cl 2p spectrum. Only Zn, Ti, O, C, and CI were detected in survey scans. All spectra were shifted by −0.50 eV to set the low-binding energy C 1s peak of the 200° C. TiOₓ-coated sample to 284.8 eV.

FIGS. 18A-18B show Valence band spectra of bare and TiOx-coated nanocrystalline ZnO films. FIG. 18A shows the low-intensity XP spectra of the secondary electron cutoff region of bare and TiOx-coated (5 cycles at 75° C., 150° C., and 200° C.) ZnO films on ITO-coated glass substrates. The Fermi level of each sample is estimated from the intercept of a linear fit of the data with the energy axis (results listed in Table S3). The data are normalized. FIG. 18B shows the Helium-II UP spectra of the valence band of these samples. The data are offset along the vertical axis for clarity. The position of the valence band maximum relative to the Fermi level (i.e., EF-EVBM) is estimated from the intercept of a linear fit of the data with the energy axis. The resulting values of EVBM are compiled in the table shown in FIG. 20.

FIGS. 19A-19B show Helium ion scattering spectra of bare and TiOₓ-coated nanocrystalline ZnO films. FIG. 19A shows survey IS spectra of four representative samples (5 cycles TiOₓ) plotted as the ratio of the scattered ion energy (Eₛ) to the incident ion energy (E₀). Vertical dashed lines denote the expected peak positions for these elements as calculated using the conventional binary elastic collision model. Data are offset along the vertical axis for clarity. FIG. 19B shows a magnified view of the Ti, CI, and O peaks. The presence of Zn peaks in all spectra indicates that the ALD layers are discontinuous (islands) and do not fully cover the ZnO surface. The decreasing Zn peak intensity with increasing ALD temperature suggests that the TiOₓCl_{y} islands increase in thickness and/or surface coverage at higher temperature.

FIG. 20 shows a table which summarizes the film elemental composition, E_{F}, and E_{VBM} as determined from the XPS and UPS data.

FIGS. 21A-21C show SEM and XRD characterization of the nanocrystalline ZnO layer. FIG. 21A shows a top-down SEM image of a 100-nm thick bare ZnO film on an ITO-coated glass substrate. FIG. 21B shows an SEM image of a similar ZnO film coated with 5 cycles of TiOₓ at 200° C. The scale bars are 100 nm. FIG. 21C shows grazing-incidence X-ray diffraction patterns of various ZnO films (bare and coated with 5 cycles of TiOₓ at 75° C., 150° C., and 200° C.) on quartz substrates. A reference ZnO powder pattern (PDF Card No. 01-078-3326) is also shown. The diffraction patterns show nanocrystalline wurtzite ZnO with little change after TiOₓ deposition, as expected for such a thin layer of ALD TiOₓ.

FIG. 22 shows a schematic of an embodiment of the present invention, wherein a layer of semiconductive particles is disposed on an interfacial layer that is disposed on a layer of semiconductive material.

FIG. 23 shows a schematic of an embodiment of the present invention, wherein a conductive substrate is provided, a layer of semiconductive material is disposed upon the conductive substrate, an interfacial layer is disposed upon the layer of semiconductive material, a layer of semiconductive particles is disposed upon the interfacial layer, and an electrical contact is disposed on the layer of semiconductive particles.

FIG. 24 shows a schematic of an embodiment of interface engineering produced by a method of the present invention.

FIG. 25 shows a schematic of an embodiment of the present invention, wherein a substrate is provided, a layer of conductive material is disposed on the substrate, a layer of semiconductive particles is disposed on the layer of conductive material, an interfacial layer is disposed on the layer of semiconductive particles, a layer of semiconductive material is disposed on the interfacial layer, and an electrical contact is disposed on the layer of semiconductive material.

FIG. 26 shows a flowchart of a method of the present invention to produce an ultrasensitive photodetector.

FIG. 27 shows a flowchart of a method of the present invention of interface engineering.

### DETAILED DESCRIPTION OF THE INVENTION

Following is a list of elements corresponding to a particular element referred to herein:
100 first embodiment of an ultrasensitive photodetector
110 substrate layer of first embodiment
120 conductive layer of first embodiment
130 semiconductive material layer of first embodiment
140 ultrathin interfacial layer of first embodiment
150 semiconductive particle layer of first embodiment
160 electrical contact of first embodiment
200 second embodiment of an ultrasensitive photodetector
230 semiconductive material layer of second embodiment
240 ultrathin interfacial layer of second embodiment
250 quantum dot layer of second embodiment
300 third embodiment of an ultrasensitive photodetector
310 conductive substrate of third embodiment
330 semiconductive material later of third embodiment
340 ultrathin interfacial layer of third embodiment
350 semiconductive particle layer of third embodiment
360 electrical contact of third embodiment
430 first semiconductive layer in an embodiment of interface engineering
435 second semiconductive layer in an embodiment of interface engineering
440 ultrathin interfacial layer in an embodiment of interface engineering
500 fourth embodiment of an ultrasensitive photodetector
510 substrate of fourth embodiment
520 conductive layer of fourth embodiment
530 semiconductive material layer of fourth embodiment
540 ultrathin interfacial layer of fourth embodiment
550 semiconductive particle layer of fourth embodiment
560 electrical contact of fourth embodiment

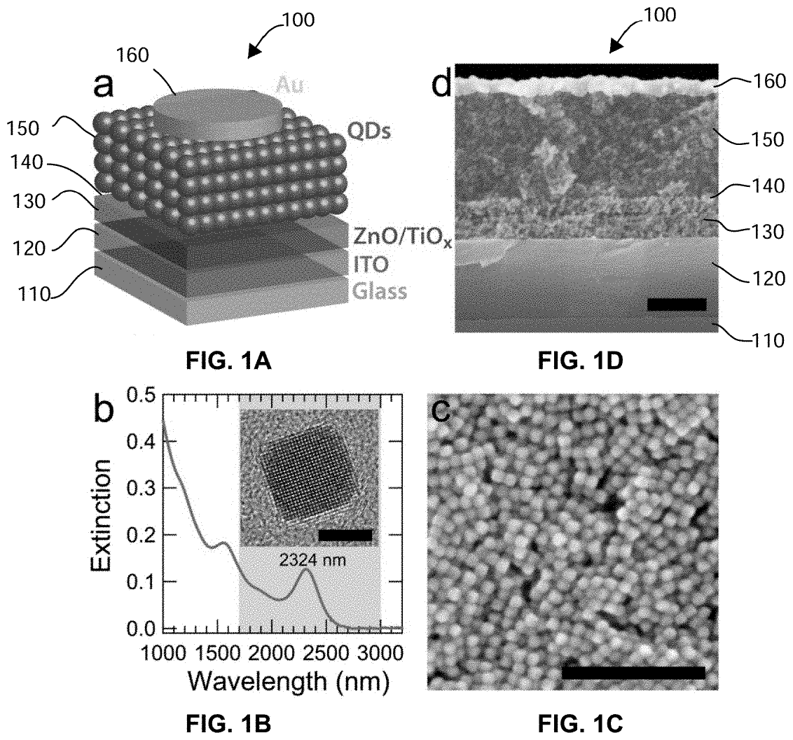

Referring now to FIGS. 1A-1D, the present invention features both methods for making high-performance quantum dot infrared photodetectors, and the resulting record-performance devices themselves. By modifying/engineering the quantum dot/semiconductor heterojunction interface with an ultrathin interlayer made by atomic layer deposition (ALD), the methods eliminate interfacial defect states, boost the photocurrent, and decrease the dark noise current of the devices, yielding record performance for eSWIR photodetection. The term “ultrathin” may refer to a layer with a thickness less than 0.6 nm. The devices may be based on quantum dot materials, which is low-cost in materials preparation and processing. The record-performance of the device is contributed by a simple method: using atomic layer deposition technique to reduce the surface defects in the junction region in the devices.

In one embodiment, the present invention features an ultrasensitive photodetector (100). The term “ultrasensitive” may refer to a photodetector with detectivity greater than 2×10¹² Jones for 2000-2550 nm. As a non-limiting example, the photodetector (100) may comprise: a substrate (110); a conductive layer (120); a layer of semiconductive material (130); an ultrathin interfacial layer (140); a layer of semiconductive particles (150); and an electrical contact (160). In some embodiments, the photodetector (100) may comprise a configuration in which the conductive layer (120) is disposed on the substrate (110); the layer of semiconductive material (130) is disposed on the conductive layer (120); the ultrathin interfacial layer (140) is disposed on the semiconductive material (130); the layer of semiconductive particles (150) is disposed on the interfacial layer (140); and the electrical contact (160) is disposed on the semiconductive particles (150) (FIG. 1a, d).

In some embodiments, the conductive layer (120) may comprise Indium Tin Oxide or another conductive material. In some embodiments, the conductive layer (120) may be transparent. In some embodiments, the semiconductive material (130) may comprise zinc oxide, another metal oxide, or another semiconductive material. In some embodiments, the interfacial layer (140) may comprise TiOₓ or another metal oxide.

According to one embodiment, the interfacial layer (140) may have been deposited by atomic layer deposition (ALD). According to another embodiment the semiconductive particles (150) may comprise quantum dots. As a non-limiting example, the quantum dots may comprise PbSe quantum dots. According to yet another embodiment, the electrical contact (160) may comprise Au or another conductive material.

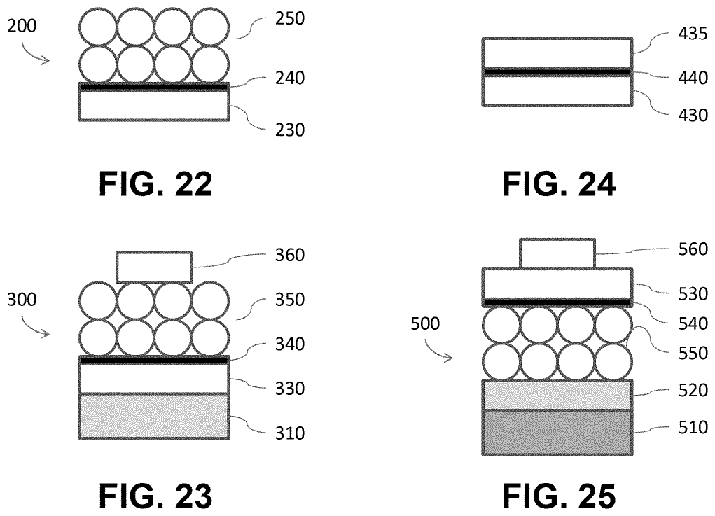

Referring to FIG. 22, in an additional embodiment, the photodetector (200) may comprise: a layer of quantum dots (250); a layer of semiconductive material (230); and an ultrathin interfacial layer (240) between the quantum dots (250) and the semiconductive material (230). In a preferred embodiment, the interfacial layer (240) may have been deposited using atomic layer deposition (ALD). In another embodiment, the interfacial layer (240) may comprise TiOₓ or another metal oxide. In still another embodiment, the TiOₓ may have been deposited using TiCl₄ and H₂O as precursor materials. In yet another embodiment, the semiconductive material (230) may comprise zinc oxide or another metal oxide. In still another embodiment, the interfacial layer (240) may passivate a plurality of defect states in the semiconductive material layer (230) or in the layer of quantum dots (250).

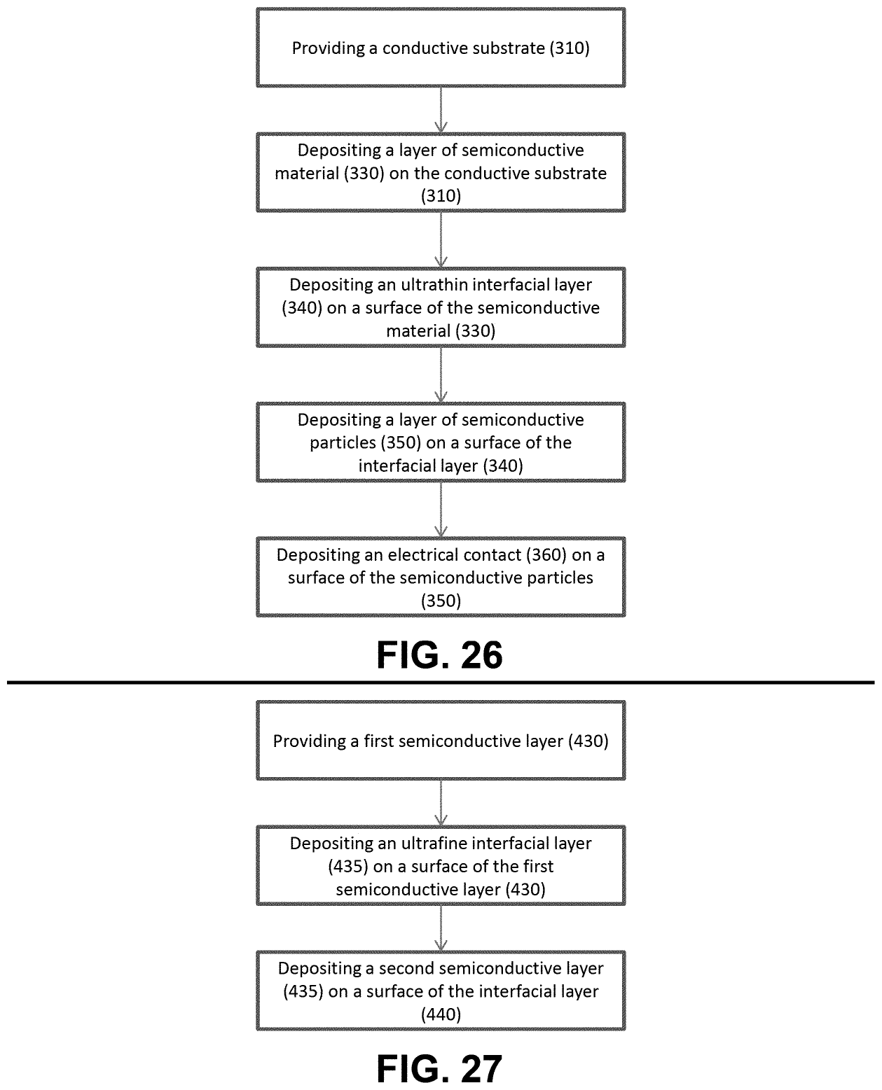

Referring to FIG. 23 and FIG. 26, in an embodiment, the present invention features a method of producing an ultrasensitive photodetector (300). As a non-limiting example, the method may comprise: providing a conductive substrate (310); depositing a layer of semiconductive material (330) on the conductive substrate (310); depositing an ultrathin interfacial layer (340) on a surface of the semiconductive material (330); depositing a layer of semiconductive particles (350) on a surface of the interfacial layer (340); and depositing an electrical contact (360) on a surface of the semiconductive particles (350). As another non-limiting example, the method may comprise: providing a conductive substrate (310); depositing a layer of semiconductive particles (350) on the conductive substrate (310); depositing an ultrathin interfacial layer (340) on a surface of the semiconductive particles (350); depositing a layer of semiconductive material (330) on a surface of the interfacial layer (340); and depositing an electrical contact (360) on a surface of the semiconductive material (330). In a preferred embodiment, the interfacial layer (330) may be disposed between the semiconductive material (330) and the semiconductive particles (350).

In some embodiments, the conductive substrate (310) may comprise an ITO-coated glass substrate or another conductive substrate. In other embodiments, the semiconductive material (330) may comprise zinc oxide, another metal oxide, or another semiconductive material. In yet other embodiments, the interfacial layer (340) may comprise TiOₓ, another metal oxide, an insulating material, a conductive material, or a semiconductive material.

In one embodiment, the interfacial layer (340) may be deposited by atomic layer deposition (ALD). As a non-limiting example, the ALD may comprise about 5 cycles. As other non-limiting examples, the ALD may comprise about 1, 2, 3, 4, 6, 7, 8, 9, 10, 12, 14, 16, 18, 20, 25, 30, 40, or 50 cycles. In one embodiment, the interfacial layer (340) may be deposited at a temperature above about 150° C. In other embodiments, the interfacial layer (340) may be deposited at a temperature above about 60° C., 70° C., 80° C., 90° C., 100° C., 110° C., 120° C., 130° C., 140° C., 160° C., 170° C., 180° C., 190° C., 200° C., 220° C., 240° C., 260° C., 280° C. or 300° C. As a non-limiting example, the interfacial layer (340) may be deposited at a temperature of about 150-200° C. As other non-limiting examples, the interfacial layer (340) may be deposited at a temperature of about 60-70° C., 70-80° C., 80-90° C., 90-100° C., 100-110° C., 110-120° C., 120-130° C., 130-140° C., 140-160° C., 160-170° C., 170-180° C., 180-190° C., 190-200° C., 200-220° C., 220-240° C., 240-260° C., 260-280° C. or 280-300° C. In some embodiments, the interfacial layer (340) may comprises a thickness of less than about 1 nm. In other embodiments, the interfacial layer (340) may comprises a thickness of less than about 0.1 nm, 0.2 nm, 0.3 nm, 0.4 nm, 0.5 nm, 0.6 nm, 0.7 nm, 0.8 nm, 0.9 nm, 1.1 nm, 1.2 nm, 1.3 nm, 1.4 nm, 1.5 nm, 1.6 nm, 1.7 nm, 1.8 nm, 1.9 nm, 2 nm, 2.5 nm, 3 nm, 4 nm, 5 nm, 6 nm, 7 nm, 8 nm, 9 nm, or 10 nm.

In some embodiments, the semiconductive particles (350) may comprise quantum dots. As a non-limiting example, the quantum dots may comprise solution-deposited, cube-shaped PdSe quantum dots. In some embodiments, the electrical contact (360) may comprise Au or another conductive material.

Referring to FIG. 24 and FIG. 27, in one embodiment, the present invention features a method of interface engineering. As a non-limiting example, the method may comprise: providing a first semiconductive layer (430); depositing an ultrathin interfacial layer (440) on a surface of the first semiconductive layer (430); and depositing a second semiconductive layer (435) on a surface of the interfacial layer (440) such that the interfacial layer (440) is positioned between the first semiconductive layer (430) and the second semiconductive layer (435). In a preferred embodiment, an interfacial electrical junction may be formed between the first semiconductive layer (430) and the second semiconductive layer (435).

In some embodiments, the interfacial layer (440) may be deposited using atomic layer deposition (ALD). In other embodiments the interfacial layer (440) may be deposited by sputtering, solution-based deposition, or chemical vapor deposition (CVD). In one embodiment, the junction may comprises a P—N type, a P—P type or an N—N type junction. In another embodiment, the junction may comprise a diode.

According to one embodiment, the interfacial layer (440) may passivates a plurality of defect states on the surface of the first semiconductive layer (430). In some embodiments, the interfacial layer (440) may comprise a semiconductive material, an insulating material, or a conductive material. In one embodiment, the interfacial layer (440) may be configured to allow for the tunneling of electrons and holes between the first semiconductive layer (430) and the second semiconductive layer (435). In another embodiment, the interfacial layer (440) may comprise an amorphous, a semicrystalline, or a crystalline structure.

In some embodiments, the first semiconductive layer (430) may comprises a metal oxide or another semiconductive material. In some embodiments, the interfacial layer (440) may comprise a metal oxide, a semiconductive material, or an insulating material. In some embodiments, the second semiconductive layer (435) may comprise quantum dots or another semiconductive material. In some embodiments, the interfacial layer (440) may have a thickness of less than about 1 nm. In some other embodiments, the junction may comprise a component of a photodetector.

Referring to FIG. 25, in one embodiment, the present invention may feature an ultrasensitive photodetector (500) comprising: a substrate (510); a conductive layer (520) disposed on the substrate (510); a layer of semiconductive particles (550) disposed on the conductive layer (520); an ultrathin interfacial layer (540) disposed on the layer of semiconductive particles (550); a layer of semiconductive material (530) disposed on the interfacial layer (540); and an electrical contact (560) disposed on the semiconductive material (530).

In an example embodiment, large PbSe quantum dots (QDs) were synthesized and purified using standard air-free techniques. To make the example devices, 65 nm thick ZnO thin films were first deposited onto ITO-coated glass substrates. Amorphous TiOₓ was deposited on the freshly-prepared ZnO films by atomic layer deposition. The PbSe QD films were then deposited onto the ZnO/TiOₓ films using a layer-by-layer spin coating procedure and ligand exchange with ethanedithiol. Evaporated top contacts (25-35 nm Au) completed the devices. Addition of the ALD interlayer boosted device detectivity by over 500 times to a record value of 2×10¹² Jones for light with wavelengths of 2000-2550 nm at room temperature and zero applied bias. These devices also displayed good speed and large linear dynamic range. This interface engineering approach is believed to allow for the production of ultrasensitive quantum dot and other types of photodetectors that operate throughout the electromagnetic spectrum. As a non-limiting example, it is believed that the method of the present invention can be used to improve the performance of any photodetector operating in any band of the electromagnetic spectrum, from the ultraviolet to the far infrared.

Referring now to FIG. 20, The XP spectra show the presence of only Zn, O, and C on the bare ZnO films. The Zn:O stoichiometry is 1:1 in these samples. The C 1s spectrum shows several types of oxidized carbon (at 289.6 eV, assigned to carboxylate carbon from adsorbed acetate, and 286.9 eV and 285.6 eV, the origin of which is unknown) in addition to a small amount of adventitious carbon. The presence of acetate is expected considering the process used to make the films (zinc acetate decomposition at 150° C.) and was confirmed with FTIR spectroscopy (not shown). The O 1s spectrum shows two peaks: lattice oxygen at 530.7 eV and surface hydroxide or acetate oxygen at 532.2 eV.

After 5 cycles of ALD TiOₓ, Ti⁴⁺ and CI peaks appear in the XP spectra and the Zn peaks decrease in intensity, consistent with the growth of a TiOₓCl_{y} coating on the nanocrystalline ZnO. Quantification of the spectra assuming complete compositional homogeneity shows that the zinc and carbon concentrations are anticorrelated, the chlorine concentration decreases, and the titanium and oxygen concentrations are constant with increasing ALD temperature to within experimental error (FIG. 20). However, it is important to account for the fact that the samples are not homogeneous. It is believed that the films consist of core/shell/shell nanocrystals with ZnO cores, an inner shell of TiOₓCl_{y}, and an outer shell of organic species. If most of the carbon is located in the outer shell of the nanocrystals, then the increasing carbon concentration in this series of samples corresponds to a thicker organic shell that suppresses signal from the underlying ZnO and TiOₓCl_{y} layers. After taking this effect into account, two major impacts of increasing the ALD temperature are discovered. First, the thickness and/or the surface coverage of the TiOₓCl_{y} layer increases with ALD temperature. It is estimated from attenuation of the zinc signal that the ALD layer increases in thickness with ALD temperature but is still only several A thick at the highest ALD temperature of 200° C. The presence of zinc peaks in all of the helium ion scattering spectra (FIGS. 19A-19B) indicates that the ALD layers are discontinuous (islands) and do not fully cover the ZnO surface. Second, the chlorine content of the TiOₓCl_{y} layer decreases with increasing ALD temperature, reaching an approximate composition of TiOCl₂ at 200° C. In summary, the surface spectroscopy data suggest that the ALD layer consists of ultrathin TiOₓCl_{y} islands that increase in thickness and surface coverage and decrease in chlorine content with increasing growth temperature.

### Example

The following is a non-limiting example of the present invention. It is to be understood that said example is not intended to limit the present invention in any way. Equivalents or substitutes are within the scope of the present invention.

Infrared cameras promise a wealth of new applications but remain too expensive and low performance for the mass market. Photodetectors operating in the so-called extended short-wave infrared (eSWIR) band at 1.7-3.0 μm are particularly underdeveloped, despite the utility of this part of the electromagnetic spectrum for navigation in adverse weather conditions, environmental monitoring, disaster response, and night vision. This example describes eSWIR photodiodes based on solution-deposited, cube-shaped PbSe quantum dots (QDs) that combine record performance with simple processing compatible with low-cost fabrication at the wafer scale. Passivation of interface states using an ultrathin layer of TiOx grown at the ZnO/QD heterojunction by atomic layer deposition yields devices with record detectivity (>2×10¹² Jones), dynamic range (>120 dB), and high speed (39 kHz) for wavelengths of 2.0-2.55 μm at room temperature and zero applied bias. The results of this example establish PbSe QDs as a leading materials platform for eSWIR photodetection and demonstrate the importance of interface engineering for boosting the performance of QD optoelectronic devices.

The advent of high-performance, inexpensive photodetectors for short-wave infrared (SWIR) light (wavelengths of 1-3 μm) would enable a variety of important civilian and military applications. Unlike mid-wave infrared (MWIR) and long-wave infrared (LWIR) cameras, SWIR cameras typically detect photons reflected from a subject that is passively illuminated by sunlight or nighttime airglow, thereby providing the sharp contrast between reflected and absorbed light needed for high-resolution day-and-night imaging. Due to reduced scattering at longer wavelengths, SWIR imagers can see through rain, fog, haze, smoke, and dust, which is useful for remote sensing, surveillance, maritime navigation, firefighting, and autonomous vehicles. The strong reflectivity contrast of materials in the SWIR band can be leveraged for mineral mapping, environmental monitoring, materials identification, forensics, and industrial quality control. In addition, hot objects (>150° C.) show appreciable SWIR emission, enabling SWIR thermal imaging for manufacturing and disaster response (e.g., monitoring fires and lava flows). However, current commercial SWIR cameras based on InGaAs, HgCdTe, InAs/Sb, and PbS/Se remain too expensive for most mass market applications. Sensor platforms that deliver better performance at much lower cost are needed for widespread non-military use of SWIR imagers.

Colloidal quantum dot solids are one of the most promising materials platforms for high-performance, inexpensive SWIR photodetectors. Quantum dots (QDs) offer strong light absorption, size-tunable bandgaps throughout the infrared, controllable electronic properties, solution processability at the wafer scale, and CMOS compatibility. Many examples of ultrasensitive PbS/Se QD photodetectors for the visible, near-infrared, and shorter-wavelength part of the SWIR (1-1.7 μm) have been reported in recent years. However, there has been little progress in making QD detectors for the longer-wavelength, so-called extended SWIR (eSWIR) at 1.7-3.0 μm because of the greater difficulty of QD synthesis, film fabrication, and interface formation for such small-bandgap PbS/Se QDs. The eSWIR is an important spectral region due to significant natural irradiance at these wavelengths, an atmospheric transmission window at 2.0-2.5 μm (the K band), and the relatively high cost and low room-temperature performance of commercial eSWIR cameras.

Materials: Lead oxide (PbO, 99.999%), selenium (99.99%), oleic acid (OA, technical grade, 90%), diphenylphosphine (DPP, 98%), 1-octadecene (ODE, 90%), 1,2-ethanedithiol (EDT, >98%), octane (anhydrous, >99%), zinc acetate (99.9%), 2-methoxyethanol (technical grade, >90%), ethylamine (99%) and acetonitrile (99.99%, anhydrous) were purchased from Sigma Aldrich and used as received. Trioctylphosphine (TOP, technical grade, >90%) was acquired from Fluka and stirred with selenium for 24 hours to form a 1 M TOP-Se stock solution. Gold pellets (99.999%) were purchased from Kurt J. Lesker Company. Patterned ITO-coated glass substrates (145±10 nm thick ITO layer) purchased from Thin Film Devices, Inc. were cleaned sequentially in acetone, deionized water, and isopropanol in an ultrasonic bath (Branson 3510) for 10 min.

QD synthesis: Large PbSe QDs were synthesized and purified using standard air-free techniques. PbO (1.09 g), OA (5.51 g), and ODE (11.20 g) were mixed and degassed in a three-neck round-bottom flask at room temperature. Then, the mixture was heated at 120° C. under vacuum to dissolve the PbO and dry the solution. After 1 hour, the Pb(OA)2 solution was heated to 220° C. under argon flow. 15 mL of a 1 M solution of TOP-Se containing 130 μL of DPP (0.75 mmol) was then rapidly injected into this hot solution. The temperature controller was then set to 160° C. and the QDs were grown for 10 min at 160° C. The reaction was quenched with a liquid nitrogen bath and injection of 15 mL of anhydrous hexane. The QDs were purified by three rounds of precipitation/redispersion using ethanol/hexane and stored as a powder in a glovebox (02<0.1 ppm, H₂O<0.1 ppm).

Preparation of TiOx-coated ZnO thin films: ˜65 nm thick ZnO thin films were made by spin coating a solution of zinc acetate (5 mM) and ethylamine (5 mM) in 2-methoxyethanol onto pre-cleaned ITO-coated glass substrates. two cycles of spin coating and annealing were used, with each cycle consisting of a coating step at 2000 rpm for 9 s, followed by annealing at 150° C. in air for 1 h and sonication in isopropanol for 10 min. The films were then stored in an oven (105° C. in air) overnight. Amorphous TiOₓ was deposited on the freshly-prepared ZnO films in a homemade cold-wall traveling wave atomic layer deposition (ALD) system within a glovebox using titanium tetrachloride (TiCl₄) and water (H₂O) at a substrate temperature of 75° C., 150° C., or 200° C. and a pressure of −0.10 Torr. Pulse and purge times were 20 ms and 60 s for TiCl₄ and 40 ms and 120 s for H₂O. The average TiOₓ growth rate was estimated to be ˜0.9 Å/cycle from SEM measurements of thicker films (50 and 100 cycles). Due to the small number of ALD cycles employed to make the TiOₓ-coated ZnO films (<8 cycles), the TiOx coatings were very thin (<1 nm) and their thicknesses were not directly measured.

QD film deposition: PbSe QD films were prepared via a layer-by-layer spin coating procedure. In brief, 70 μL of a 30 mg/mL suspension of PbSe QDs in octane was spin cast onto TiOₓ/ZnO/ITO/glass or plain quartz substrates using a 3 s ramp to 2000 rpm for 40 s. The substrates were then dipped into a 1 mM solution of EDT in dry acetonitrile for 20 s, removed from the solution and dried under a gentle nitrogen stream. On average, each spin coating step resulted in a film thickness of ˜25 nm. Five to ten steps were used to make QD films with thicknesses ranging from 140 nm to 260 nm.

Photodiode fabrication and testing: Top contacts (˜25 nm Au) were evaporated onto the QD/TiOx/ZnO/ITO/glass device stacks through a shadow mask in a glovebox-based thermal evaporator (7×10⁻⁷ Torr base pressure) at a rate of 0.5 Å/s, yielding four devices per substrate (each with a 3.54 mm² active area). The samples were mounted to a water-cooled stage and maintained at 20° C. during the evaporation to avoid sintering of the QDs. Current-voltage characteristics were measured in a glovebox with a Keithley 2636B source meter and a stabilized tungsten IR light source (Thorlabs SLS202L) filtered through a 2250 nm±250 nm band pass filter (Thorlabs FB2250-500). IR neutral density filters (Newport 5240, 5241, 5243) were used to adjust the light intensity for measurements of photodiode dynamic range. The light intensity was measured with a pyroelectric radiometer (Model Rk-5710, LaserProbe, Inc.) or calculated from the measured transmittance of the ND filters. Dark J-V data were measured in a light-tight Faraday cage wrapped in aluminum foil. The transient response of the devices was measured using an infrared light-emitting diode (Thorlabs LED2350P, A=2350 nm) modulated by a wavefunction generator (Agilent 33620A) to produce square-wave light pulses (20 ns rise/fall times) with a pulse width of 5-200 μs at a frequency of 100-1000 Hz. The output current was sent to a low-noise current preamplifier (SR570, Stanford Research Systems) and the resulting voltage measured with an oscilloscope (Tektronix TDS1012). The noise current of the devices was measured using the preamplifier and a spectrum analyzer (Agilent 8561E) driven by LabVIEW software. The sensitivity of the preamplifier was set to 500 nA/V for samples with bare ZnO and 20 nA/V for all samples with TiOx interlayers. The noise current measurements were limited to a frequency range of 10-100 Hz by the sensitivity-bandwidth product of the preamplifier and the DC noise of the spectrum analyzer.

Characterization: Transmission electron microscopy was performed on a JEOL JEM-2100F TEM operating at 200 kV. Scanning electron microscopy (SEM) imaging was performed on a FEI Magellan 400L XHR SEM operating at 10 kV and 50 pA. Optical extinction, transmittance, and reflectance spectra were acquired with a PerkinElmer Lambda 950 spectrophotometer equipped with a 60 mm integrating sphere. Fourier transform infrared (FTIR) spectra were acquired with a Jasco 4100 FTIR spectrometer on double-side polished silicon substrates. Florescence spectra were captured by a Cary Eclipse 900 fluorimeter. Grazing incidence X-ray diffraction patterns were obtained on a Rigaku SmartLab X-ray diffractometer.

X-ray photoelectron spectra (XPS) were acquired on a Kratos AXIS Supra spectrometer using monochromatic Al Kα radiation with an X-ray power of 225 W. Low-intensity XPS (LIXPS) was performed with an X-ray power of 7.5 W. Ultraviolet photoelectron spectra (UPS) spectra were collected using He I (21.2 eV) and He II (40.8 eV) radiation. Ion scattering spectroscopy (ISS) was performed using a 1 keV primary He+ beam at a 40° incidence angle relative to the sample surface. A hemispherical analyzer was used to collect either photoelectrons or scattered ions normal to the sample surface. The instrument was energy calibrated using sputter-cleaned Ag and Au foils. Survey XPS spectra were collected at a 1.0 eV step size and a dwell time of 100 ms using a pass energy of 160 eV, while high-resolution elemental XPS spectra were collected at 20 eV pass energy using a 0.1 eV step size, 100 ms dwell time and an average of three scans per spectrum. A 9 V sample bias was applied for LIXPS and UPS measurements. The work function of the sample surface was derived from the secondary electron cutoff edge of LIXPS and UPS (He I) spectra acquired at 5 eV pass energy using a 0.01 eV step size, 100 ms dwell time and an average of five scans per spectrum. UPS valence band spectra were acquired with 10 eV pass energy, 0.02 eV step size and an average of ten scans per spectrum. Work function and valence band edge energies were estimated from the intercept of a linear fit of the data with the baseline.

This example uses interface engineering by atomic layer deposition (ALD) to lower the dark current and boost the photocurrent of PbSe QD eSWIR photodiodes, yielding uncooled (300 K) devices with record specific detectivity of >2×10¹² cm Hz^{1/2} W⁻¹ at 2.0-2.55 μm (10-fold higher than commercial eSWIR photodetectors operating at room temperature), high linear dynamic range (>120 dB), and sufficient speed (˜39 kHz) for many applications. In addition to demonstrating record-performance eSWIR photodetectors that can be manufactured at low cost, this example also shows that ALD interface modification is a powerful tool for passivating interface states and modifying energy level alignments to improve the performance of heterojunctions in optoelectronic devices.

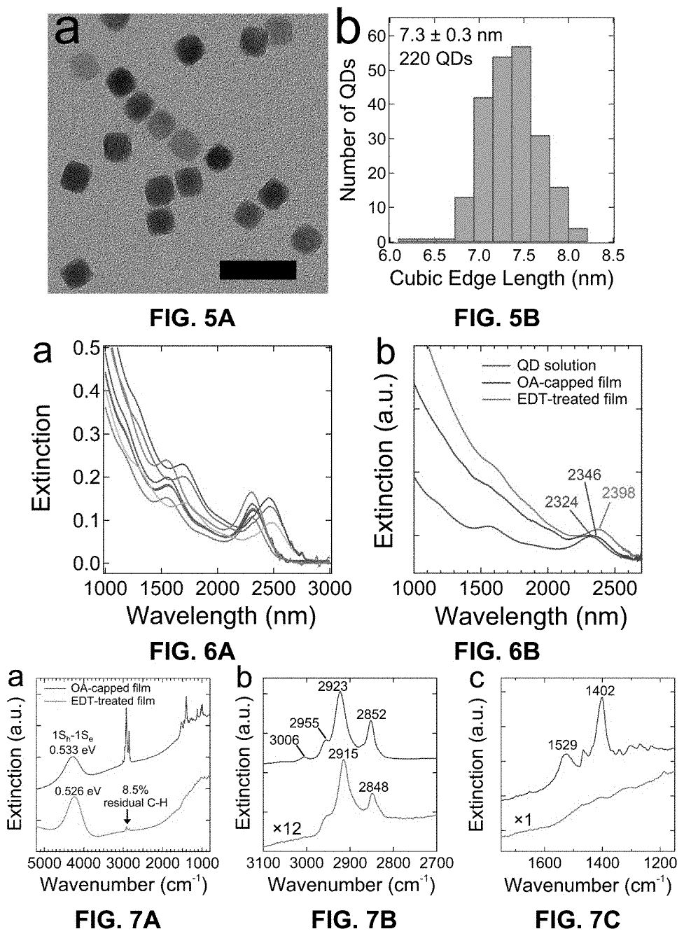

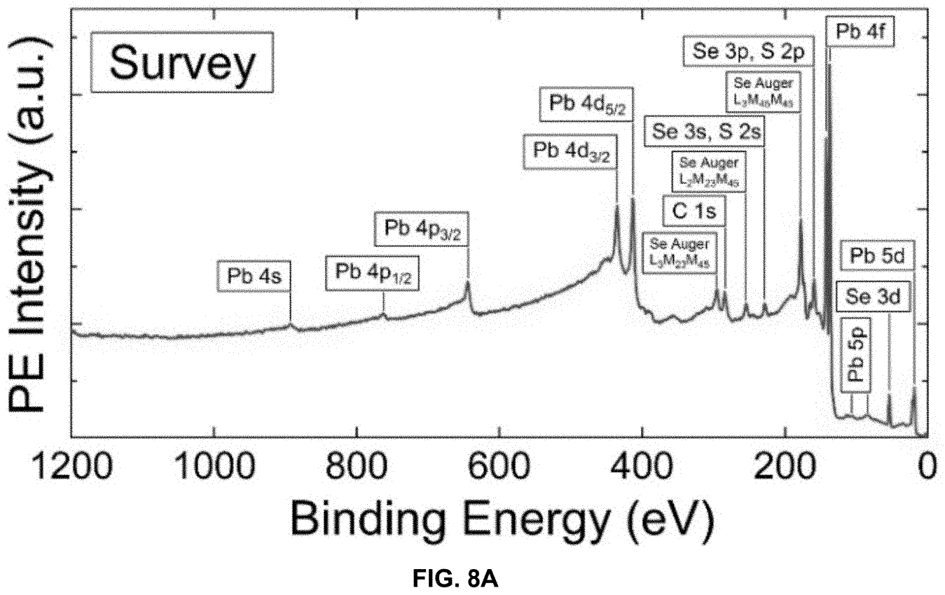

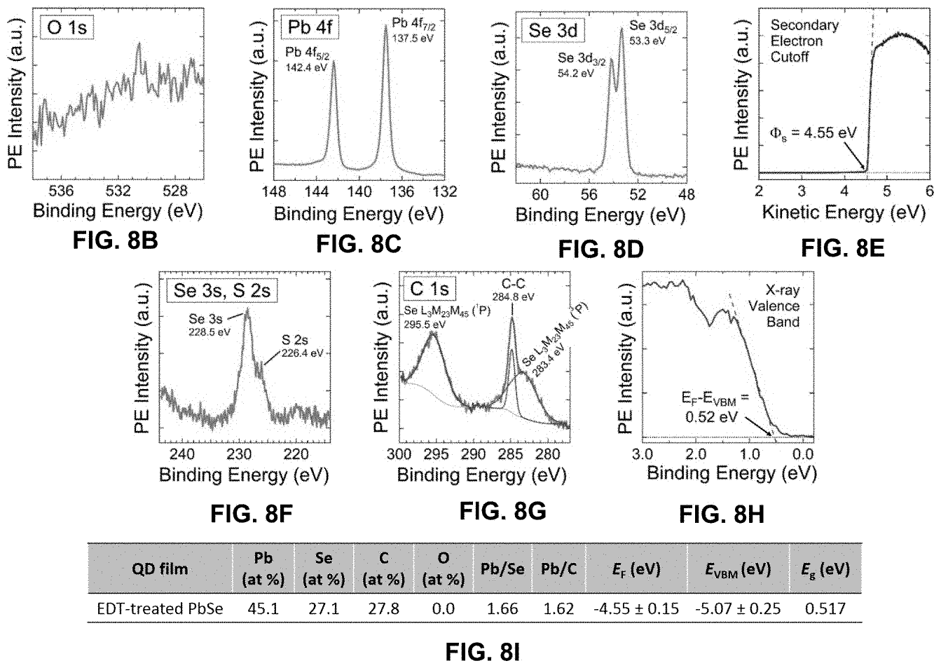

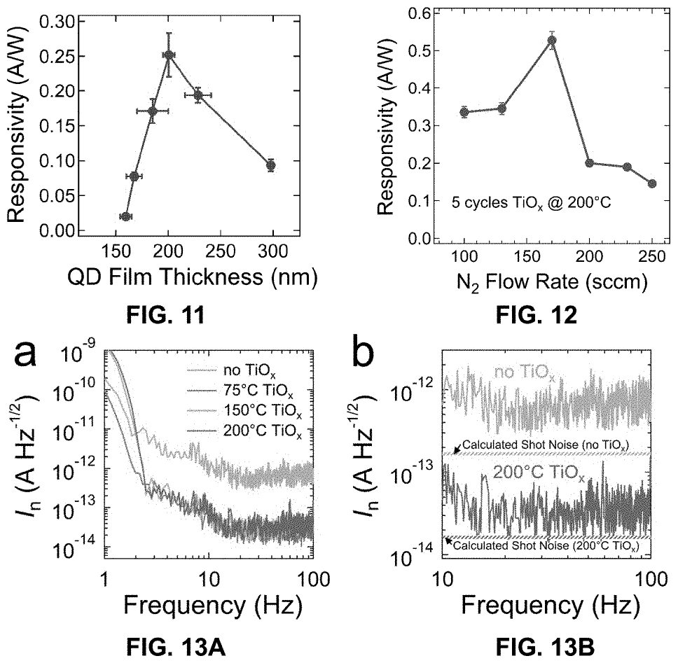

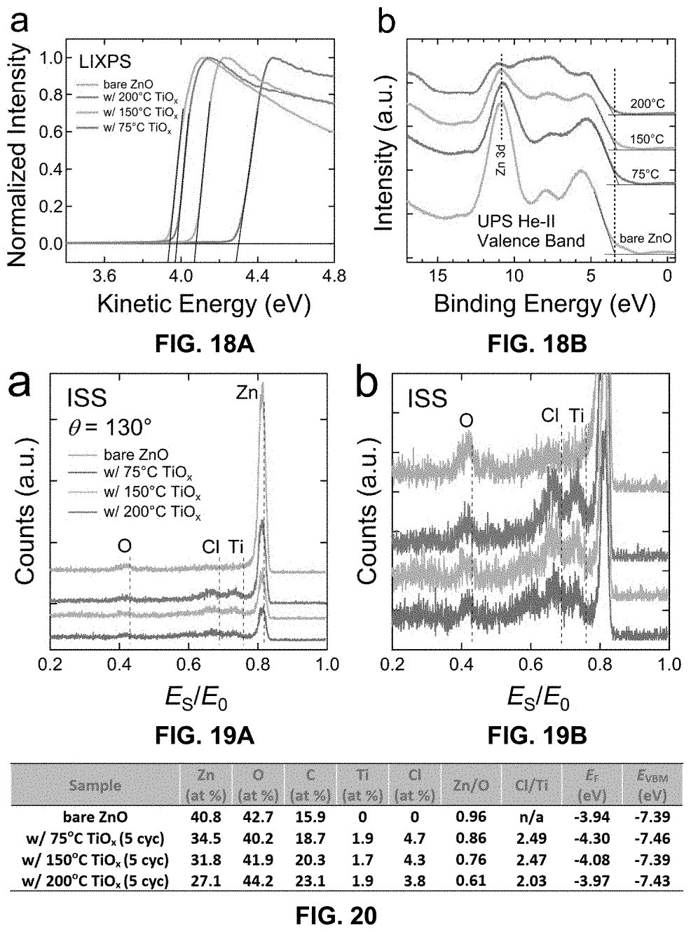

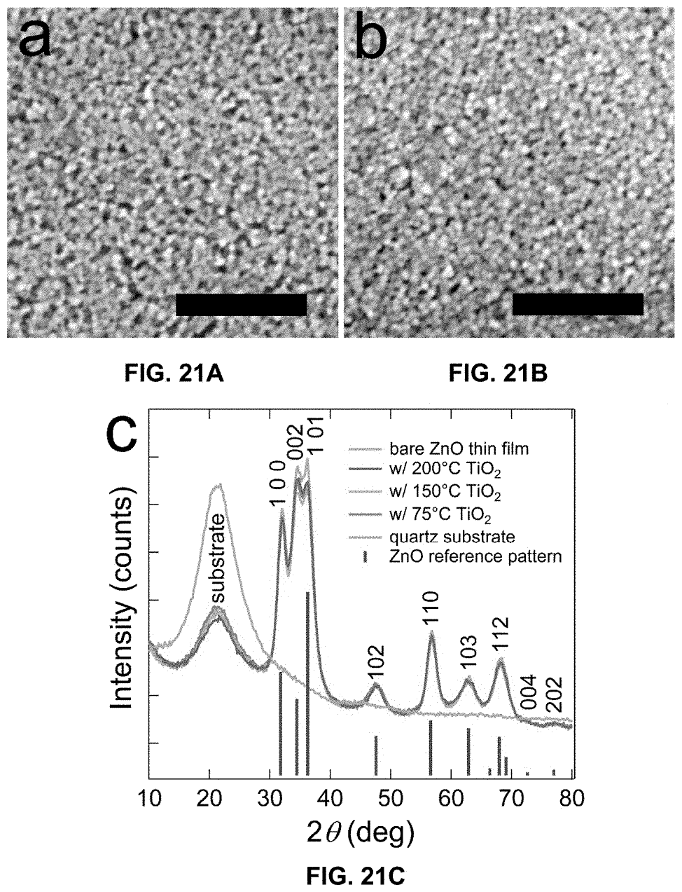

In this example, the eSWIR photodiodes are based on planar nanocrystalline ZnO/PbSe QD heterojunctions sandwiched between ITO and Au contacts (see FIG. 1A and Methods). The colloidal PbSe QDs are truncated cubes with a cubic edge length of 7.3±0.3 nm (4% polydispersity) and an absorption onset at ˜2700 nm (0.46 eV) in tetrachloroethylene solution (FIG. 1B). These QDs were deposited onto 65-nm thick nanocrystalline ZnO films on ITO-coated glass substrates by multiple cycles of spin coating and ligand exchange with 1,2-ethanedithiol (EDT), yielding uniform, dense, and optically perfect QD films measured by cross-section scanning electron microscopy to be 160-300 nm thick, depending on the number of spin coat cycles used (FIGS. 1C-1D). As a result of the decreased inter-QD distance after ligand exchange, the absorption onset of the EDT-treated films redshifts to ˜2775 nm (0.45 eV). Additional characterization of the QD films can be found in FIGS. 5A-21C. Circular gold top contacts (˜25 nm thick, 3.54 mm² area) were evaporated onto the QD films to complete the devices (FIG. 1A and FIG. 1D).

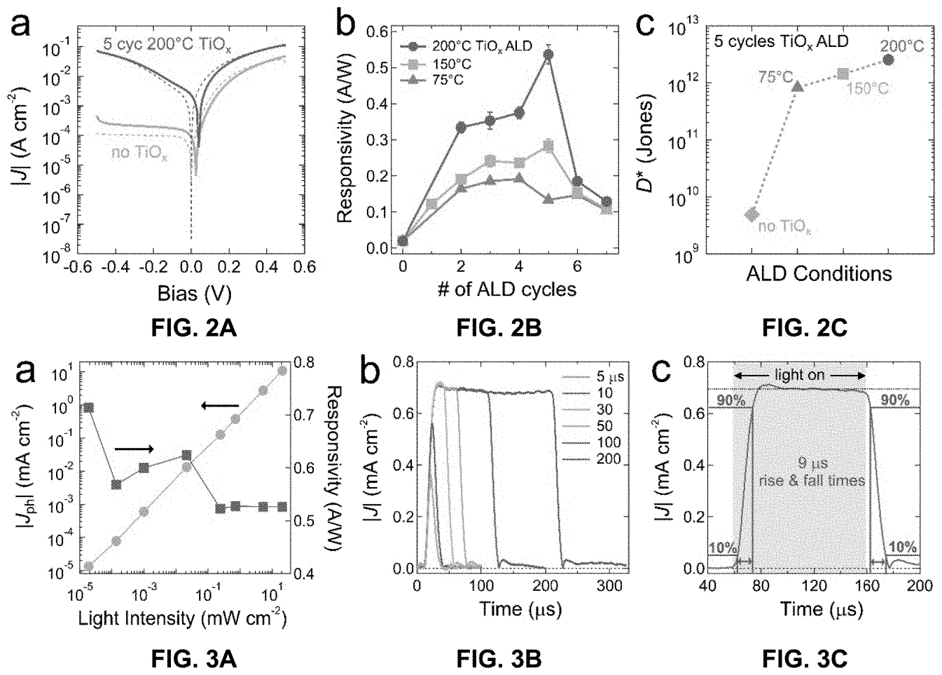

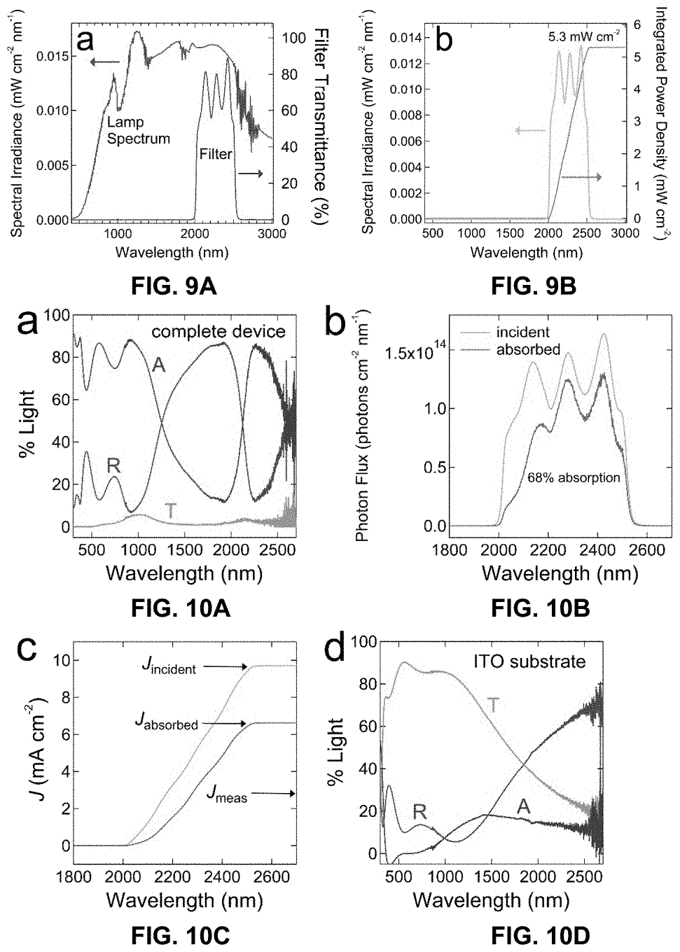

A discovery of the present invention was that modifying the ZnO/QD interface with an ultrathin (<0.6 nm) interlayer of TiOx deposited by ALD from TiCl₄ and water greatly improves the performance of these devices for eSWIR photodetection. FIG. 2A compares typical current-voltage (J-V) curves for devices with and without 5 cycles of ALD TiOx grown on the ZnO/ITO/glass substrates at 200° C. prior to QD film deposition. Although devices with the TiOx interlayer show much worse rectification and larger dark current under reverse bias, their performance at zero applied bias improves dramatically, with 90-fold lower dark current (2.8×10-8 A cm-2 with the interlayer compared to 2.5×10-6 A cm-2 without it) and 27-fold higher photocurrent under eSWIR illumination from a filtered tungsten lamp (A=2.0-2.55 μm, 5.3 mW cm-2). Therefore, these detectors are operated at zero bias (the so-called photovoltaic mode). The ALD interface modification increases the responsivity of the detectors (the ratio of photocurrent to incident optical power) from 0.019 to 0.54 NW. Using the spectral irradiance of the incident light (FIGS. 9A-9B) and the detector absorptance (FIGS. 10A-10D), an external quantum efficiency (EQE) of 29% and an internal quantum efficiency of 43% in the 2.0-2.55 μm band for the devices with the TiOx interlayer are calculated. The responsivity increases with increasing ALD growth temperature from 75° C. to 200° C. and peaks at ˜5 ALD cycles (FIG. 2B). This behavior may reflect several temperature and thickness-dependent factors, particularly the reactivity of the ZnO surface, the coverage, density, and composition of the TiOx coating, and the resulting electronic defects at the ZnO/TiOx and TiOx/QD interfaces.

Apart from high responsivity, low noise is also important because noise determines the minimum detectable optical power. The noise current of our devices was measured at zero bias in order to calculate their specific detectivity (D*), the main figure of merit for the sensitivity of photodetectors. D* is the signal-to-noise ratio for a detector of 1 cm2 area illuminated by 1 W of optical power measured at a bandwidth of 1 Hz, and it can be expressed as

$${D}^{*} = \frac{R ( λ ) \cdot \sqrt{A}}{{I}_{n} ( f )} ,$$

where R(A) is the detector responsivity, A is its area, and Iₙ(f) is its current noise spectral density (in units of A Hz^{-1/2}). Iₙ is found to be flat within the measured frequency range (10-100 Hz) and dominated by thermal noise, with a calculated shot noise that is 2.5-4.5 times smaller than the measured noise (FIGS. 13A-13B). The addition of the TiOₓ interlayer (5 cycles at 200° C.) decreases Iₙ by a factor of nineteen (to 39 fA Hz^{-1/2} at 10-100 Hz) and boosts D* by a factor of ˜520 to a record value of D*=2.5×10¹² cm Hz^{1/2} W⁻¹ (Jones) at 300 K. The detectivity of these devices is an order of magnitude higher than commercial photodetectors operating in this wavelength range at room temperature. Note that D* increases with ALD growth temperature from 75° C. to 200° C. (FIG. 2C). Interface engineering at even higher ALD temperatures may further improve D* to approach the background-limited intrinsic performance (BLIP) limit (e.g., 1×10¹³ Jones at 2.3 μm and 300 K).

In addition to record detectivity, these QD photodetectors have high dynamic range and good speed. Using infrared neutral density filters, a linear photoresponse was measured across six decades of optical power density (from Pₘᵢₙ=19 nW cm⁻² to Pₘₐₓ=21 mW cm⁻²), indicating that the devices have a high linear dynamic range

$$LDR = 20 log ( \frac{{P}_{max}}{{P}_{min}} ) of > 120 dB$$

(FIG. 3A). The actual LDR is probably significantly higher, but equipment limitations (e.g., the relatively low maximum irradiance of the infrared lamp) prevented measurements over a wider range of light intensities. The temporal response of the detectors was tested with a light-emitting diode (λ=2350 nm, 0.77 mW cm⁻²) producing square-wave light pulses of 5-200 μs pulse width and ˜20 ns rise time at 1 kHz. A square-wave photoresponse was observed for pulse widths >25 μs, while shorter pulses were faster than the device response time and resulted in distorted peaks of progressively smaller amplitude (FIG. 3B). The 10-90% rise and fall times of the square-wave photocurrent signals were nearly identical at ˜9 μs (FIG. 3C). A conservative estimate of the corresponding −3 dB bandwidth (BW) is given as

$$BW ≅ \frac{0.35}{{t}_{rise}} ,$$

which is equal to 38.9 kHz for these devices. This bandwidth is sufficient for most imaging applications. Moreover, given the low carrier mobility of EDT-treated QD films, significant improvements in bandwidth should be achievable by employing better ligand chemistries and coupling strategies that boost the carrier mobility.

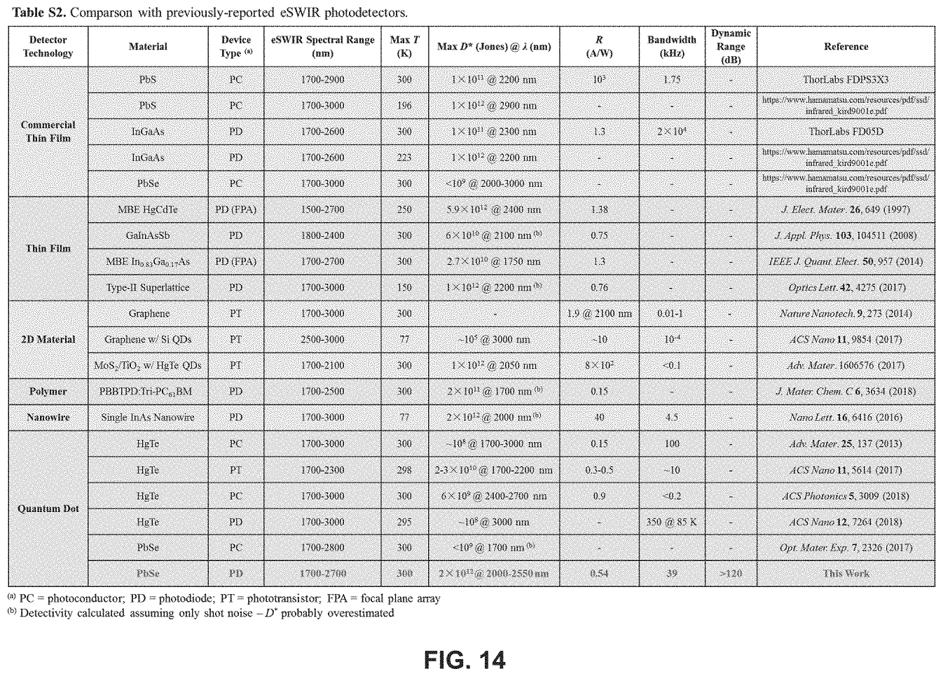

Recently-reported eSWIR photodetectors based on PbSe and HgTe QD photoconductors HgTe QD photodiodes and phototransistors, and phototransistors made from 2D materials (e.g., graphene, MoS2) sensitized with HgTe QDs or highly-doped Si QDs have lower D*, linear dynamic range, and/or speed than the devices of the present invention. Chen et al. reported an HgTe QD phototransistor with D*˜2×10¹⁰ Jones at 2000-2200 nm. Ni et al. described a graphene phototransistor sensitized with plasmonic Si QDs showing D*>10¹² Jones out to 1870 nm. Huo et al. recently reported an MoS₂ phototransistor sensitized with HgTe QDs showing D*˜1×10¹² Jones at 2000-2100 nm. The devices of the present invention offer larger linear dynamic range, higher bandwidth, and simpler fabrication/integration at the wafer scale. The table in FIG. 14 summarizes the performance of previously-reported eSWIR devices.

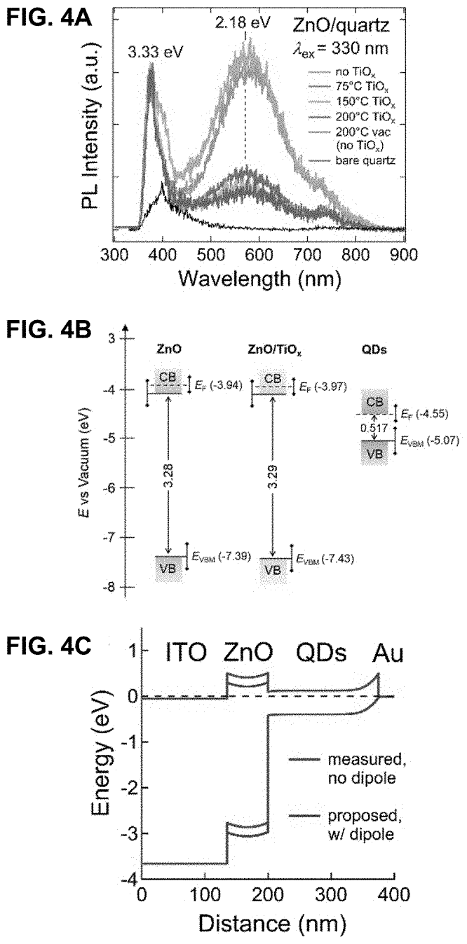

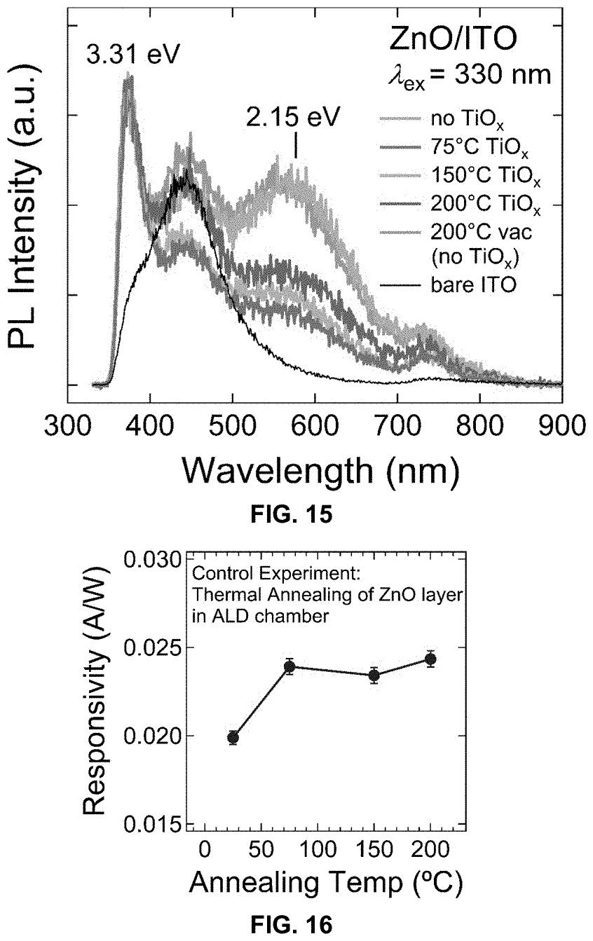

Photoluminescence (PL) and photoelectron spectroscopy were used to determine how the TiOx interlayer improves the detector performance. The PL spectra of the ZnO films before and after TiOx deposition were compared (FIG. 4A and FIG. 15). While bare ZnO films showed weak visible defect emission at 569 nm (2.18 eV), this emission was greatly suppressed by TiOx deposition (FIG. 4A), suggesting that most of the ZnO defect states responsible for the visible PL are passivated by the TiOx coating. A strong correlation was observed between lower defect PL and improved device detectivity. Control experiments showed that thermal annealing in the ALD chamber without TiOx deposition had little effect on the PL spectra (FIG. 4A) or detectivity (FIG. 16). Without wishing to limit the present invention to any particular theory or mechanism, it is believed that the TiOₓ interlayer removes interfacial defects at the ZnO/QD junction, which increases the photocurrent and decreases the dark current at zero bias.

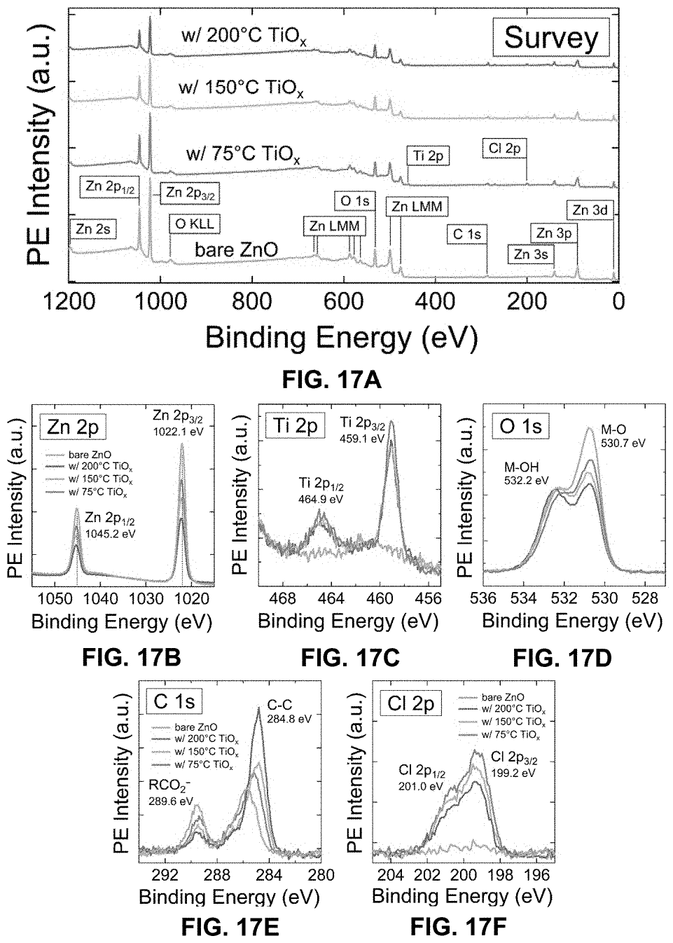

X-ray and ultraviolet photoelectron spectroscopy (XPS and UPS) were used to establish the band diagram of the devices and to determine if the decreased rectification observed after ALD (FIG. 2A) is caused by changes in band alignment at the ZnO/QD interface. FIGS. 4B-4C show the measured energy levels of the bare ZnO, TiOx-coated ZnO, and PbSe QD films, together with the resulting band diagram of devices with and without the TiOx interlayer. Based on the XPS/UPS data, all three films are n-type, there is insignificant shifting of the band edges and Fermi level upon coating ZnO films with TiOx, and the devices behave as n-n isotype heterojunctions with a potential barrier for majority carriers of ˜0.4 eV at the oxide/QD interface (red plot in FIG. 4C). J-V measurements of control devices showed that the contacts are ohmic. Since the band edges of the films are unaffected by the TiOₓ coating, it is believed that the decreased rectification of devices with TiOₓ interlayers may result from an interface dipole that forms during solution deposition of the QDs on the TiOₓ-coated ZnO surface and lowers the height of the potential barrier (blue plot in FIG. 4C), resulting in a more linear J-V curve. Indeed, XPS shows a large amount of chlorine in the “TiOx” layer—as noted previously—and this amorphous oxyhalide surface layer should result in very different interface electrostatics than a pure ZnO surface. See FIGS. 17A-21C for detailed surface spectroscopy and structural characterization data of the ZnO and TiOx-coated ZnO films.

This example has demonstrated record-performance extended SWIR photodetectors based on solution-deposited cube-shaped PbSe QDs. After ALD interface engineering of the ZnO/QD heterojunction using an ultrathin layer of TiOₓ, these devices show a room-temperature detectivity of over 2×10¹² Jones at 2000-2550 nm, good responsivity (0.54 NW, or 29% EQE), large linear dynamic range (>120 dB) and high bandwidth (˜39 kHz), all without the need for applied bias. Without wishing to limit the present invention to any particular theory or mechanism, it appears that the ALD TiOₓ interlayer boosts device performance by passivating electronically-active defects at the ZnO/QD interface. In contrast to most competing technologies, these eSWIR photodetectors are simple to fabricate at the wafer scale and work at room temperature. Long-term air stability may be achieved either by encapsulation with ALD metal oxides, or polymers. Inversion of the device stack may allow for integration onto silicon readout integrated circuits (ROICs) to build large-area, high-resolution and low-cost PbSe QD imagers for eSWIR applications.

As used herein, the term “about” refers to plus or minus 10% of the referenced number.

Although there has been shown and described the preferred embodiment of the present invention, it will be readily apparent to those skilled in the art that modifications may be made thereto which do not exceed the scope of the appended claims. Therefore, the scope of the invention is only to be limited by the following claims. In some embodiments, the figures presented in this patent application are drawn to scale, including the angles, ratios of dimensions, etc. In some embodiments, the figures are representative only and the claims are not limited by the dimensions of the figures. In some embodiments, descriptions of the inventions described herein using the phrase “comprising” includes embodiments that could be described as “consisting essentially of” or “consisting of”, and as such the written description requirement for claiming one or more embodiments of the present invention using the phrase “consisting essentially of” or “consisting of” is met.

What is claimed is:

1. A method of interface engineering, the method comprising:
a. providing a first semiconductive layer (430);
b. depositing an ultrathin interfacial layer (440) on a surface of the first semiconductive layer (430) by atomic layer deposition (ALD); and
c. depositing a second semiconductive layer (435) on a surface of the interfacial layer (440) such that the interfacial layer (440) is positioned between the first semiconductive layer (430) and the second semiconductive layer (435);
wherein an interfacial electrical junction is formed between the first semiconductive layer (430) and the second semiconductive layer (435).

2. The method of claim 1, wherein the junction comprises a P—N type, a P—P type or an N—N type junction.

3. The method of claim 1, wherein the junction comprises a diode.

4. The method of claim 1, wherein the interfacial layer (440) passivates a plurality of defect states on the surface of the first semiconductive layer (430).

5. The method of claim 1, wherein the interfacial layer (440) comprises a semiconductive material.

6. The method of claim 1, wherein the interfacial layer (440) comprises an insulating material.

7. The method of claim 1, wherein the interfacial layer (440) is configured to allow for the tunneling of electrons and holes between the first semiconductive layer (430) and the second semiconductive layer (435).

8. The method of claim 1, wherein the interfacial layer (440) comprises an amorphous, a semicrystalline, or a crystalline structure.

9. The method of claim 1, wherein the first semiconductive layer (430) comprises a metal oxide.

10. The method of claim 1, wherein the interfacial layer (440) comprises a metal oxide.

11. The method of claim 1, wherein the second semiconductive layer (435) comprises quantum dots.

12. The method of claim 1, wherein the interfacial layer (440) has a thickness of less than about 1 nm.

13. The method of claim 1, wherein the junction comprises a component of a photodetector.

14. An ultrasensitive photodetector (100) comprising:
a. a substrate (110);
b. a conductive layer (120);
c. a layer of semiconductive material (130);
d. an ultrathin interfacial layer (140);
e. a layer of semiconductive particles (150); and
f. an electrical contact (160).
wherein the interfacial layer (140) is disposed between the semiconductive material (130) and the semiconductive particles (150) by atomic layer deposition (ALD).

15. The photodetector (100) of claim 14, wherein the conductive layer (120) comprises Indium Tin Oxide.

16. The photodetector (100) of claim 14, wherein the semiconductive material (130) comprises zinc oxide.

17. The photodetector (100) of claim 14, wherein the interfacial layer (140) comprises TiOₓ or another metal oxide.

18. The photodetector (100) of claim 14, wherein the semiconductive particles (150) comprise quantum dots.

19. The photodetector (100) of claim 18, wherein the quantum dots comprise PbSe quantum dots.

20. The photodetector (100) of claim 14, wherein the electrical contact (160) comprises Au or another conductive material.
